(19) United States
(12) Patent Application Publication
(10) Pub. No.: US 2025/0063921 A1
(43) Pub. Date: Feb. 20, 2025

(54) DISPLAY DEVICE

(71) Applicant: Samsung Display Co., LTD., Yongin-si, Gyeonggi-do (KR)

(72) Inventors: Ki Nyeng KANG, Yongin-si (KR); Guanghai JIN, Yongin-si (KR); Sun Kwang KIM, Yongin-si (KR)

(21) Appl. No.: 18/670,492

(22) Filed: May 21, 2024

(30) Foreign Application Priority Data
Aug. 14, 2023 (KR) 10-2023-0106075

(51) Int. Cl. H10K 59/80; H10K 59/122; H10K 59/65

(52) U.S. Cl. CPC H10K 59/873; H10K 59/122; H10K 59/65

(57) ABSTRACT

A display device includes: a substrate including a display area and a middle area; a light-emitting element on the display area, and including: a pixel electrode; an emissive layer; and a common electrode; an edge structure on the middle area, and including a lower metal stack and an upper metal stack; and a first inorganic encapsulation film on the light-emitting element and the edge structure. The lower metal stack includes a first sub-metal layer, a second sub-metal layer, and a third sub-metal layer. The upper metal stack includes a fourth sub-metal layer and a fifth sub-metal layer. A width of the first sub-metal layer is greater than a width of the third sub-metal layer, the width of the third sub-metal layer is greater than a width of the second sub-metal layer, and a width of the fifth sub-metal layer is greater than a width of the fourth sub-metal layer.

### CROSS-REFERENCE TO RELATED APPLICATION(S)

The present application claims priority to and the benefit of Korean Patent Application No. 10-2023-0106075, filed on Aug. 14, 2023, in the Korean Intellectual Property Office, the entire disclosure of which is incorporated by reference herein.

### BACKGROUND

### 1. Field

Aspects of embodiments of the present disclosure relate to a display device.

### 2. Description of the Related Art

As information-oriented society evolves, various demands for display devices are ever increasing. Display devices may be flat-panel display devices, such as a liquid-crystal display device, a field emission display device, and an organic light-emitting display device. From among such flat panel display devices, a light-emitting display device includes a light-emitting element that may emit light on its own, so that each of the pixels of the display panel may emit light by themselves. Accordingly, a light-emitting display device may display images without a backlight unit that supplies light to the display panel.

A display device includes a display area where images are displayed, and a non-display area around the display area, for example. Recently, the width of the non-display area is ever decreasing in order for viewers to get more immersed in the content displayed on the display area, and to increase the aesthetics of the display device.

The above information disclosed in this Background section is for enhancement of understanding of the background of the present disclosure, and therefore, it may contain information that does not constitute prior art.

### SUMMARY

A display device may include a through hole in which one or more optical devices, such as a camera, is disposed. The non-display area around (e.g., adjacent to) the through hole may block permeation of moisture into the display area.

One or more embodiments of the present disclosure are directed to a display device having high luminance, while blocking moisture.

However, the aspects and features of the present disclosure are not limited thereto, and other aspects and features of the present disclosure will be apparent to those having ordinary skill in the art from the following description.

According to one or more embodiments of the present disclosure, a display device includes: a substrate including a display area surrounding a through hole, and a middle area between the through hole and the display area; a light-emitting element on the display area of the substrate, and including: a pixel electrode; an emissive layer on the pixel electrode; and a common electrode on the emissive layer; an edge structure on the middle area of the substrate, and including a lower metal stack and an upper metal stack; and a first inorganic encapsulation film on the light-emitting element and the edge structure. The lower metal stack includes a first sub-metal layer, a second sub-metal layer on the first sub-metal layer, and a third sub-metal layer on the second sub-metal layer. The upper metal stack is on the lower metal stack, and includes a fourth sub-metal layer on the third sub-metal layer, and a fifth sub-metal layer on the fourth sub-metal layer. A width of the first sub-metal layer is greater than a width of the third sub-metal layer, the width of the third sub-metal layer is greater than a width of the second sub-metal layer, and a width of the fifth sub-metal layer is greater than a width of the fourth sub-metal layer.

In an embodiment, the edge structure may include an inorganic layer between the lower metal stack and the upper metal stack, and a width of the inorganic layer may be greater than or equal to the width of the third sub-metal layer.

In an embodiment, the width of the fourth sub-metal layer may be greater than the width of the second sub-metal layer.

In an embodiment, a thickness of the fourth sub-metal layer may be greater than a thickness of the fifth sub-metal layer.

In an embodiment, the display device may further include: a pixel-defining layer on the display area of the substrate, and exposing at least a part of the pixel electrode; a first bank layer on the pixel-defining layer; and a second bank layer on the first bank layer, and including a side surface protruding from a side surface of the first bank layer. The first bank layer may include a same material as that of the fourth sub-metal layer, and the second bank layer may include a same material as that of the fifth sub-metal layer.

In an embodiment, the display device may further include a pixel-defining layer on the display area of the substrate, and exposing at least a part of the pixel electrode, and the inorganic layer may include a same material as that of the pixel-defining layer.

In an embodiment, the display device may further include a thin-film transistor between the substrate and the light-emitting element in the display area, and including a semiconductor layer, a source electrode, a drain electrode, and a gate electrode. The source electrode and the drain electrode may include: a layer including a same material as that of the first sub-metal layer; a layer including a same material as that of the second sub-metal layer; and a layer including a same material as that of the third sub-metal layer.

In an embodiment, the display device may further include: an organic encapsulation film on the first inorganic encapsulation film; a second inorganic encapsulation film on the organic encapsulation film; and a first dam between the substrate and the first inorganic encapsulation film in the middle area. The first dam may include a first side surface facing the through hole, and a second side surface opposite to the first side surface. The first inorganic encapsulation film and the second inorganic encapsulation film may be in contact with each other on the first side surface of the first dam.

In an embodiment, the organic encapsulation film may be on the second side surface of the first dam.

In an embodiment, the edge structure may be between the first dam and the through hole.

In an embodiment, the edge structure may overlap with the organic encapsulation film in a thickness direction of the substrate.

In an embodiment, the first sub-metal layer, the third sub-metal layer, and the fifth sub-metal layer may include titanium (Ti), and the second sub-metal layer and the fourth sub-metal layer may include aluminum (Al).

In an embodiment, the common electrode may be in contact with the side surface of the first bank layer.

In an embodiment, a maximum vertical distance from the substrate to the common electrode may be smaller than a maximum vertical distance from the substrate to the second bank layer.

In an embodiment, the display device may further include: an organic pattern on the second bank layer, and including a same material as that of the emissive layer; and an electrode pattern on the organic pattern, and including a same material as that of the common electrode. The emissive layer and the organic pattern may be spaced from each other, and the common electrode and the electrode pattern may be spaced from each other.

In an embodiment, the substrate may include an inclined surface toward the through hole.

In an embodiment, the display device may further include an optical device located in the through hole.

According to one or more embodiments of the present disclosure, a display device includes: a substrate including a display area surrounding a through hole, and a middle area between the through hole and the display area; a light-emitting element on the display area of the substrate, and including: a pixel electrode; an emissive layer on the pixel electrode; and a common electrode on the emissive layer; an edge structure on the middle area of the substrate, and including a lower metal stack and an upper metal stack; and a first inorganic encapsulation film on the light-emitting element and the edge structure. The lower metal stack includes a first sub-metal layer, a second sub-metal layer on the first sub-metal layer, and a third sub-metal layer on the second sub-metal layer. The upper metal stack is on the lower metal stack, and includes a fourth sub-metal layer on the third sub-metal layer, and a fifth sub-metal layer on the fourth sub-metal layer. A thickness of the fourth sub-metal layer is greater than a thickness of the fifth sub-metal layer. The first inorganic encapsulation film is in contact with a lower surface of the third sub-metal layer, and a lower surface and an upper surface of the fifth sub-metal layer.

In an embodiment, the edge structure may include an inorganic layer between the lower metal stack and the upper metal stack, and a width of the inorganic layer may be greater than or equal to a width of the third sub-metal layer.

In an embodiment, a width of the first sub-metal layer may be greater than a width of the third sub-metal layer, and a width of the fourth sub-metal layer may be greater than a width of the second sub-metal layer.

According to one or more embodiments of the present disclosure, a display device may include a structure in which two tip structures are stacked on each other around (e.g., adjacent to) a through hole, so that permeation of moisture may be effectively blocked and luminance may be increased.

However, the present disclosure is not limited to the aspects and features described above. Additional aspects and features will be set forth, in part, in the description that follows with reference to the figures, and in part, may be apparent from the description and the figures, or may be learned by practicing one or more of the presented embodiments of the present disclosure.

### BRIEF DESCRIPTION OF DRAWINGS

The above and other aspects and features of the present disclosure will be more clearly understood from the following detailed description of the illustrative, non-limiting embodiments with reference to the accompanying drawings, in which:

FIG. 1 is a perspective view of a display device according to an embodiment of the present disclosure;

FIG. 2 is a plan view showing a display panel according to an embodiment of the present disclosure;

FIG. 3 is a cross-sectional view showing an example of the display device taken along the line I-I′ of FIG. 1;

FIG. 4 is a cross-sectional view showing an example of the display device of FIG. 3 when a circuit board is bent;

FIG. 5 is a cross-sectional view of a display area of a display device according to an embodiment of the present disclosure;

FIG. 6 is a cross-sectional view of a display area of a display device according to an embodiment of the present disclosure;

FIG. 7 is an enlarged cross-sectional view showing the area A1 of FIG. 6;

FIG. 8 is an enlarged plan view of the area II of FIG. 2;

FIG. 9 is a cross-sectional view showing an example of the display panel taken along the line III-III′ of FIG. 8;

FIG. 10 is an enlarged cross-sectional view showing an example of the area A2 of FIG. 9;

FIG. 11 is an enlarged cross-sectional view showing another example of the area A2 of FIG. 9;

FIGS. 12-14 are enlarged cross-sectional views showing examples of the areas A3 of FIGS. 10 and 11; and

FIGS. 15-19 are cross-sectional views showing sequential processes of a method of fabricating a display device according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

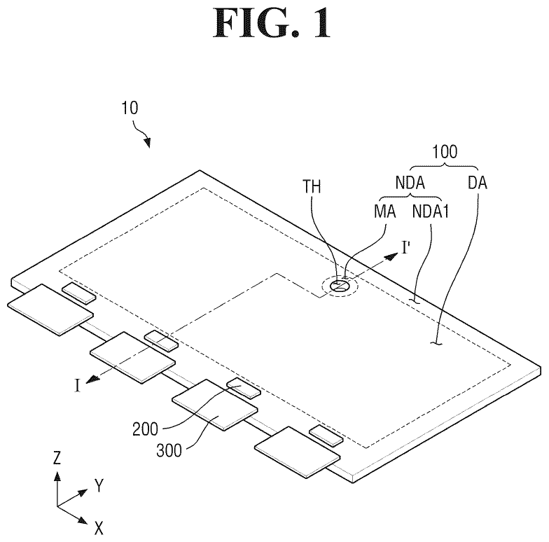

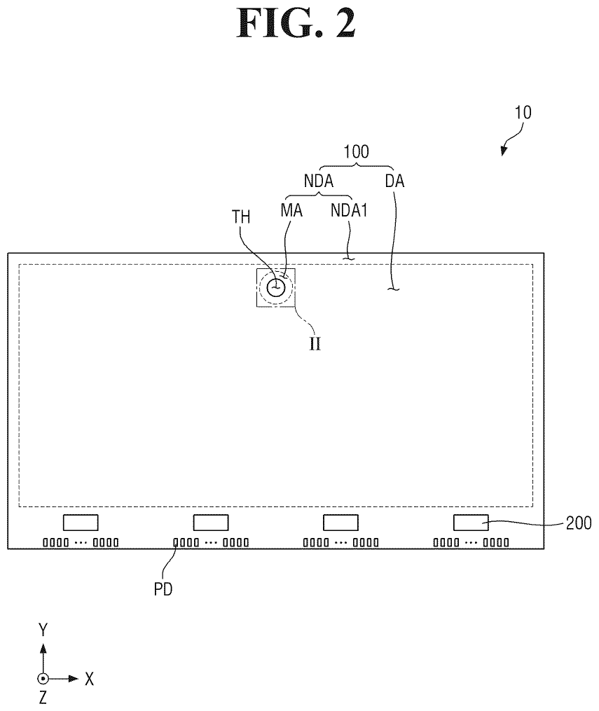

FIG. 1 is a perspective view of a display device according to an embodiment of the present disclosure. FIG. 2 is a plan view showing a display panel according to an embodiment of the present disclosure.

Referring to FIG. 1, according to an embodiment of the present disclosure, a display device 10 is a device for displaying moving images and/or still images. The display device 10 may be used as a display screen of various suitable portable electronic devices, such as a mobile phone, a smart phone, a tablet PC, a smart watch, a watch phone, a mobile communications terminal, an electronic notebook, an electronic book, a portable multimedia player (PMP), a navigation device, and a ultra mobile PC (UMPC), as well as the display screen of various suitable products, such as a television, a notebook, a monitor, a billboard, and the Internet of Things (IoT) devices.

According to an embodiment of the present disclosure, the display device 10 may be a light-emitting display device, such as an organic light-emitting display device that uses organic light-emitting diodes, a quantum-dot light-emitting display device including a quantum-dot light-emitting layer, an inorganic light-emitting display device including an inorganic semiconductor, and a micro-LED display device that uses micro or nano light-emitting diodes (micro LEDs or nano LEDs). Hereinafter, for convenience of illustration, the display device 10 may be described in more detail in the context of an organic light-emitting display device as a representative example. However, it should be understood that the present disclosure is not limited thereto.

The display device 10 according to an embodiment may include a display panel 100, a display driver 200, and a circuit board 300.

The display panel 100 may be formed in a rectangular plane having longer sides extending in a first direction (e.g., the x-axis direction), and shorter sides extending in a second direction (e.g., the y-axis direction) crossing or intersecting the first direction (e.g., the x-axis direction). Each of the corners where a longer side extending in the first direction (e.g., the x-axis direction) meets a shorter side extending in the second direction (e.g., the y-axis direction) may be formed at a right angle, or may be rounded with a curvature. The shape of the display panel 100 when viewed from the top (e.g., in a plan view) is not limited to a quadrangular shape, and may be formed in a different polygonal shape, a circular shape, or an elliptical shape.

The display panel 100 may be formed to be flat or substantially flat, but the present disclosure is not limited thereto. For example, the display panel 100 may be formed at left and right ends, and may include a curved portion having a constant curvature or a varying curvature. In addition, the display panel 100 may be flexible so that it can be curved, bent, folded, or rolled.

The display panel 100 may include a display area DA where images are displayed, and a non-display area NDA where no image is displayed.

The display area DA may occupy most of the area of the display panel 100. The display area DA may be disposed at the center of the display panel 100. In the display area DA, pixels, each including a plurality of emission areas, may be disposed to display images.

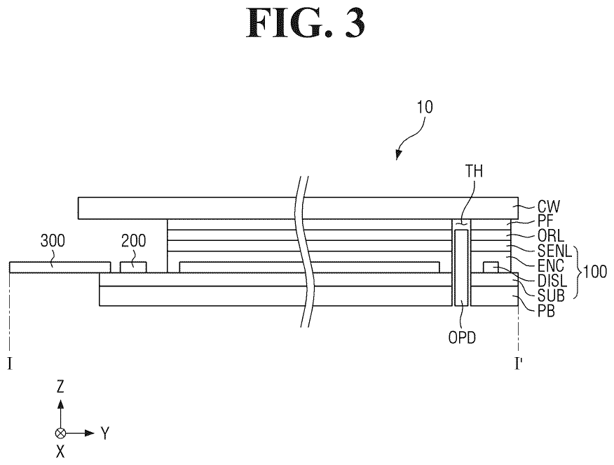

The non-display area NDA may include a middle area MA and a first non-display area NDA1. The display area DA may surround (e.g., around peripheries of) the middle area MA and a through hole TH. The middle area MA may surround (e.g., around a periphery of) the through hole TH, and may be located between the display area DA and the through hole TH. The through hole TH may be a hole that allows light to transmit through, and may be an area where an optical device OPD (e.g., see FIG. 3) is disposed.

The first non-display area NDA1 may be disposed adjacent to the display area DA. The first non-display area NDA1 may be on the outer side of the display area DA. The first non-display area NDA1 may be disposed to surround (e.g., around a periphery of) the display area DA. The first non-display area NDA1 may be an edge area of the display panel 100.

Referring to FIGS. 1 and 2, the first non-display area NDA1 may include display pads PD, the display drivers 200, and the circuit boards 300.

The display pads PD may be disposed at one edge of the display panel 100. For example, the display pads PD may be disposed at the lower edge of the display panel 100. The display pads PD may be connected to the display drivers 200 and the circuit boards 300.

The display drivers 200 may generate and output signals and voltages for driving the display panel 100. In more detail, the display drivers 200 may generate and output data voltages, supply voltages, scan timing signals, and the like. The display driver 200 may apply a supply voltage to a voltage line, and may supply gate control signals to a gate driver.

The display drivers 200 may be disposed between the display pads PD and the display area DA in the first non-display area NDA1. The display drivers 200 may be attached to the first non-display area NDA1 of the display panel 100 by a chip on glass (COG) technique. As another example, the display drivers 200 may be attached to the circuit boards 300 by a chip on plastic (COP) technique.

The circuit boards 300 may be disposed on the display pads DP that are disposed at one edge of the display panel 100. The circuit boards 300 may be attached to the display pads PD using a conductive adhesive member, such as an anisotropic conductive film and/or an anisotropic conductive adhesive. Accordingly, the circuit boards 300 may be electrically connected to signal lines of the display panel 100. The circuit boards 300 may be flexible printed circuit boards or flexible films, such as chip on films.

A bending area may be located between the display drivers 200 and the display area DA in the first non-display area NDA1. The bending area may be bent, such that the display drivers 200 and the circuit boards 300 are disposed under the display panel 100. The display drivers 200 and the circuit boards 300 that are bent at the bending area may overlap with the display area DA in the third direction (e.g., the z-axis direction).

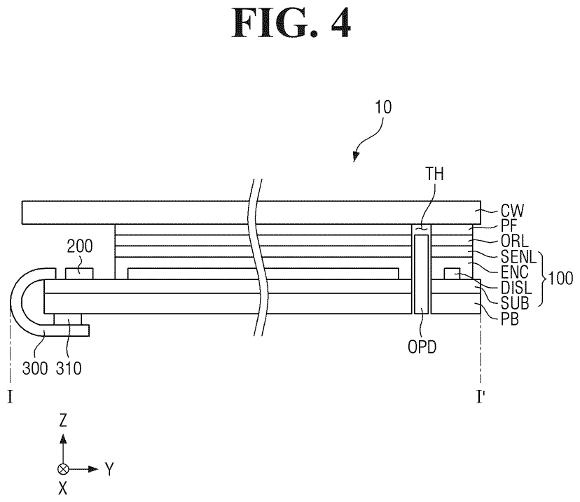

FIG. 3 is a cross-sectional view showing an example of the display device taken along the line I-I′ of FIG. 1. FIG. 4 is a cross-sectional view showing an example of the display device of FIG. 3 when a circuit board is bent.

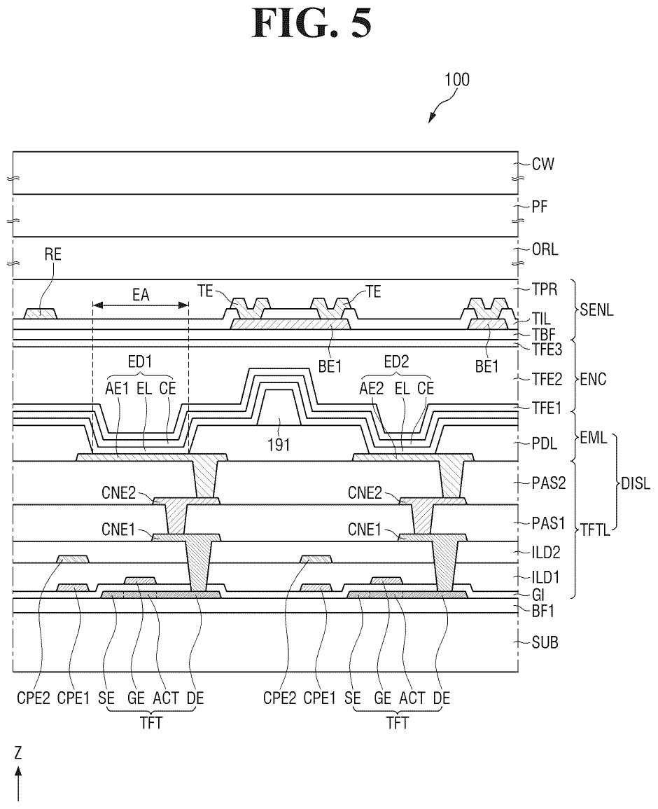

Referring to FIG. 3, the display device 10 according to an embodiment may include a display panel 100, a polarizing film PF, a cover window CW, and a panel bottom cover PB. The display panel 100 may include a substrate SUB, a display layer DISL including a thin-film transistor layer TFTL and an emission material layer EML (e.g., see FIG. 5), a thin-film encapsulation layer ENC, a touch sensor layer SENL, and an organic planarization layer ORL.

The substrate SUB may be a base substrate or a base member. The substrate SUB may be a flexible substrate that can be bent, folded, or rolled. For example, the substrate SUB may include, but is not limited to, a polymer resin such as polyimide PI. According to another embodiment, the substrate SUB may include a glass material or a metal material.

The thin-film transistor layer TFTL may be disposed on the substrate SUB. The thin-film transistor layer TFTL may include thin-film transistors. Each of the thin-film transistors may include a semiconductor region, a source electrode, a drain electrode, and a gate electrode.

The emission material layer EML may be disposed on the thin-film transistor layer TFTL. The emission material layer EML may include a plurality of light-emitting elements, each including a pixel electrode, a common electrode, and an emissive layer to emit light, and a pixel-defining film for defining the pixels. The plurality of light-emitting elements may be disposed in the display area DA.

The thin-film encapsulation layer ENC may be disposed on the emission material layer EML. The thin-film encapsulation layer ENC may cover the upper and side surfaces of the emission material layer EML in order to prevent or substantially prevent permeation of oxygen and/or moisture into the emission material layer EML. The thin-film encapsulation layer ENC may include at least one inorganic film, and at least one organic film.

The touch sensor layer SENL may be disposed on the thin-film encapsulation layer ENC. The touch sensor layer SENL may include sensor electrodes. The touch sensor layer SENL may sense a user's touch using the sensor electrodes.

The polarizing film PF may be disposed on the touch sensor layer SENL.

The polarizing film PF may be disposed on the display panel 100 in order to reduce a reflection of external light. The polarizing film PF may include a first base member, a linear polarizer, a retardation film such as a quarter-wave (λ/4) plate, and a second base member. The first base member, the retardation film, the linear polarizer, and the second base member of the polarizing film PF may be sequentially stacked on the display panel 100.

The cover window CW may be disposed on the polarizing film PF. The cover window CW may be attached onto the polarizing film PF by a transparent adhesive member, such as an optically clear adhesive (OCA) film.

The panel bottom cover PB may be disposed on the lower surface of the substrate SUB. The lower surface of the substrate SUB may be opposite to the upper surface. In other words, the lower surface of the substrate SUB may be opposite to the surface where the thin-film transistor layer TFTL, the emission material layer EML, the thin-film encapsulation layer ENC, and the touch sensor layer SENL are located. The panel bottom cover PB may be attached to the lower surface of the substrate SUB by an adhesive member. The adhesive member may be a pressure-sensitive adhesive (PSA).

The panel bottom cover PB may include at least one of a light-blocking member for absorbing light incident from outside, a buffer member for absorbing external impact, and/or a heat dissipating member for efficiently discharging heat.

The display device 10 may further include an optical device OPD. The optical device OPD may output or receive light in infrared, ultraviolet, and/or visible ranges. For example, the optical device OPD may be an optical sensor that senses light incident on the display device 10, such as a proximity sensor, an illuminance sensor, a camera sensor, and/or an image sensor.

The optical device OPD may be disposed in the through hole TH. The through hole TH may allow light to pass through it, and may be a physical hole penetrating through the panel bottom cover PB, the display panel 100, and the polarizing film PF. However, the present disclosure is not limited thereto. For example, the through hole TH may penetrate through the panel bottom cover PB, but may not penetrate through the display panel 100 or the polarizing film PF. The cover window CW may be disposed to cover the through hole TH.

Referring to FIG. 4, the display drivers 200 and the circuit boards 300 may be bent, such that they may be located under the display panel 100. The circuit boards 300 may be attached to the lower surface of the panel bottom cover PB by an adhesive member 310. The adhesive member 310 may be a pressure-sensitive adhesive.

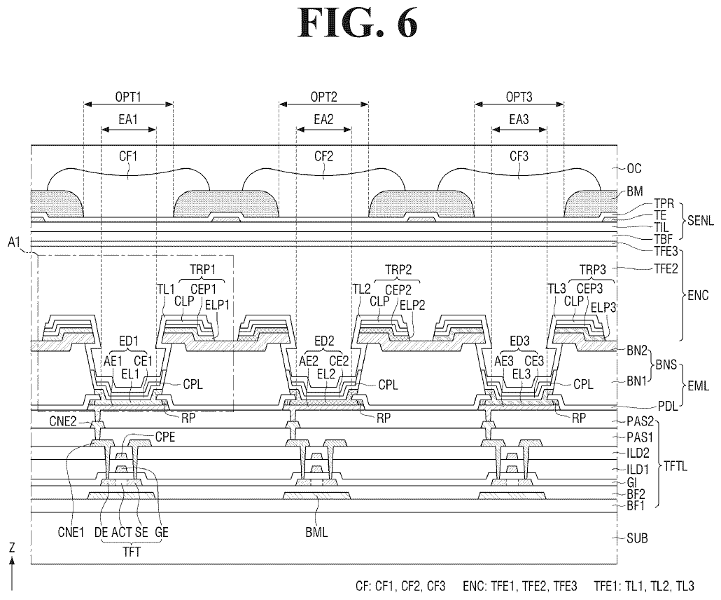

FIG. 5 is a cross-sectional view of a display area of a display device according to an embodiment of the present disclosure. FIG. 6 is a cross-sectional view of a display area of a display device according to an embodiment of the present disclosure.

Referring to FIG. 5, the display panel 100 according to an embodiment may be a light-emitting display panel including light-emitting elements ED1 and ED2, each including an emissive layer EL. The emissive layer EL and/or a common electrode CE of FIG. 5 may be formed not only where they overlap with pixel electrodes AE1 and AE2, but also where they do not overlap with the pixel electrodes AE1 and AE2.

Referring to FIG. 6, the display panel 100 according to an embodiment may be a light-emitting display panel including light-emitting elements ED1, ED2, and ED3 including emissive layers EL1, EL2, and EL3 that are spaced apart from one another. While the common electrode CE of FIG. 5 is illustrated as being continuously extended in the display area DA, the emissive layers EL1, EL2, and EL3 and the common electrodes CE1, CE2, and CE3 of FIG. 6 may be separated from one another, and may be formed in the openings defined by a bank structure BNS.

The display device 10 may include a plurality of emission areas EA1, EA2, and EA3 arranged in the display area DA. The emission areas EA1, EA2, and EA3 may include first emission areas EA1, second emission areas EA2, and third emission areas EA3 that emit light of different colors from each other. The first to third emission areas EA1, EA2, and EA3 may emit red, green, and blue light, respectively. The colors of the light emitted from the emission areas EA1, EA2, and EA3 may vary depending on the kind of light-emitting elements ED1, ED2, and ED3 (e.g., see FIG. 6), which will be described in more detail below. For example, the first emission area EA1 may output a first light of a red color, the second emission area EA2 may output a second light of a green color, and the third emission area EA3 may output a third light of a blue color. However, the present disclosure is not limited thereto.

Each of the first to third emission areas EA1, EA2, and EA3 may be defined by a corresponding opening defined by a pixel-defining layer PDL, or a corresponding opening defined by a bank structure BNS, which will be described in more detail below.

In the display device 10, one first emission area EA1, two second emission areas EA2, and one third emission area EA3 that are disposed to be adjacent to one another may form a single pixel group. The single pixel group may represent black-and-white or color grayscales by including the emission areas EA1, EA2, and EA3 for emitting light of different colors for each other. However, the present disclosure is not limited thereto. The combination of the emission areas EA1, EA2, and EA3 forming a single pixel group may be variously modified depending on the arrangement of the emission areas EA1, EA2, and EA3, and the colors of the light emitted from the emission areas EA1, EA2, and EA3.

Referring to FIGS. 5 and 6, the display panel 100 may include a substrate SUB, a thin-film transistor layer TFTL, an emission material layer EML, a thin-film encapsulation layer ENC, and a touch sensor layer SENL.

The substrate SUB may be the same or substantially the same as that described above, and thus, redundant description may not be repeated.

The thin-film transistor layer TFTL may include a first buffer layer BF1, a bottom metal layer BML, a second buffer layer BF2, a thin-film transistor TFT, a gate insulator GI, a first interlayer dielectric layer ILD1, a capacitor electrode CPE, a second interlayer dielectric layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic film capable of preventing or substantially preventing permeation of air and/or moisture. For example, the first buffer layer BF1 may include a plurality of inorganic films that are stacked on one another alternately.

Optionally, the bottom metal layer BML may be disposed on the first buffer layer BF1. For example, the bottom metal layer BML may include (e.g., may be made up of) a single layer or multiple layers of one or more of molybdenum (Mo), aluminum (Al), chromium (Cr), gold (Au), titanium (Ti), nickel (Ni), neodymium (Nd), copper (Cu), or a suitable alloy thereof.

Optionally, the second buffer layer BF2 may cover the first buffer layer BF1 and the bottom metal layer BML. The second buffer layer BF2 may include an inorganic film capable of preventing or substantially preventing permeation of air and/or moisture. For example, the second buffer layer BF2 may include a plurality of inorganic films that are stacked on one another alternately.

The thin-film transistor TFT may be disposed on the first buffer layer BF1 and/or the second buffer layer BF2, and may be part of (e.g., may form or be included in) a pixel circuit of the pixel from among a plurality of pixels. For example, the thin-film transistor TFT may be a driving transistor or a switching transistor of the pixel circuit. The thin-film transistor TFT may include a semiconductor layer ACT, a source electrode SE, a drain electrode DE, and a gate electrode GE.

The semiconductor layer ACT may be disposed on the first buffer layer BF1 and/or the second buffer layer BF2. The semiconductor layer ACT may overlap with the bottom metal layer BML and the gate electrode GE in the thickness direction, and may be insulated from the gate electrode GE by a gate insulator GI. The material of a part of the semiconductor layer ACT may be made conductive to form the source electrode SE and the drain electrode DE.

The gate electrode GE may be disposed on the gate insulator GI. The gate electrode GE may overlap with the semiconductor layer ACT, with the gate insulator GI interposed therebetween.

The gate insulator GI may be disposed on the semiconductor layer ACT. For example, the gate insulator GI may cover the first buffer layer BF1 or the second buffer layer BF2, may cover the semiconductor layer ACT, and may insulate the semiconductor layer ACT from the gate electrode GE. The gate insulator GI may include a contact hole through which the first connection electrode CNE1 passes.

The first interlayer dielectric layer ILD1 may cover the gate electrode GE and the gate insulator GI. The first interlayer dielectric layer ILD1 may include a contact hole through which the first connection electrode CNE1 passes. The contact holes of the first interlayer dielectric layer ILD1 may be connected to the contact holes of the gate insulator GI and the contact holes of the second interlayer dielectric layer ILD2.

The capacitor electrode CPE may be disposed on the first interlayer dielectric layer ILD1. According to an embodiment, there may be a plurality of capacitor electrodes CPE. The first capacitor electrode CPE1 may be disposed on the gate insulator GI. The second capacitor electrode CPE2 may be disposed on the first interlayer dielectric layer ILD1, and may overlap with the first capacitor electrode CPE1 in the thickness direction. According to another embodiment, the capacitor electrode CPE may overlap with the gate electrode GE in the thickness direction, so that the capacitor electrode CPE and the gate electrode GE may form a capacitance.

The second interlayer dielectric layer ILD2 may cover the capacitor electrode CPE and the first interlayer dielectric layer ILD1. The second interlayer dielectric layer ILD2 may include a contact hole through which the first connection electrode CNE1 passes. The contact hole of the second interlayer dielectric layer ILD2 may be connected to the contact hole of the first interlayer dielectric layer ILD1 and the contact hole of the gate insulator GI.

The first connection electrode CNE1 may be disposed on the second interlayer dielectric layer ILD2. The first connection electrode CNE1 may electrically connect the drain electrode DE of the thin-film transistor TFT with the second connection electrode CNE2. The first connection electrode CNE1 may be inserted into a contact hole formed in the second interlayer dielectric layer ILD2, the first interlayer dielectric layer ILD1, and the gate insulator GI, to be in contact with the drain electrode DE of the thin-film transistor TFT. The first connection electrode CNE1 may include (e.g., may be made up of) a single layer or multiple layers of one or more of molybdenum (Mo), aluminum (Al), chromium (Cr), gold (Au), titanium (Ti), nickel (Ni), neodymium (Nd), copper (Cu), or a suitable alloy thereof. The first connection electrode CNE1 may include a layer including the same material as that of a first sub-metal layer 411, a layer including the same material as that of a second sub-metal layer 412, and a layer including the same material as that of a third sub-metal layer 413, which will be described in more detail below.

The first passivation layer PAS1 may cover the first connection electrode CNE1 and the second interlayer dielectric layer ILD2. The first passivation layer PAS1 may protect the thin-film transistor TFT. The first passivation layer PAS1 may include a contact hole through which the second connection electrode CNE2 passes.

The second connection electrode CNE2 may be disposed on the first passivation layer PAS1. The second connection electrode CNE2 may electrically connect the first connection electrode CNE1 with the pixel electrodes AE1, AE2, and AE3 of the light-emitting elements ED1, ED2, and ED3. The second connection electrode CNE2 may be inserted into a contact hole formed in the first passivation layer PAS1, to be in contact with the first connection electrode CNE1.

The second passivation layer PAS2 may cover the second connection electrode CNE2 and the first passivation layer PAS1. The second passivation layer PAS2 may include contact holes through which the pixel electrodes AE1, AE2, and AE3 of the light-emitting elements ED1, ED2, and ED3 pass.

The emission material layer EML may be disposed on the thin-film transistor layer TFTL. Referring to FIG. 5, the emission material layer EML may include the light-emitting elements ED1 and ED2 and the pixel-defining layer PDL. Referring to FIG. 6, the emission material layer EML may include the light-emitting elements ED1, ED2, and ED3, the pixel-defining layer PDL, and the bank structure BNS.

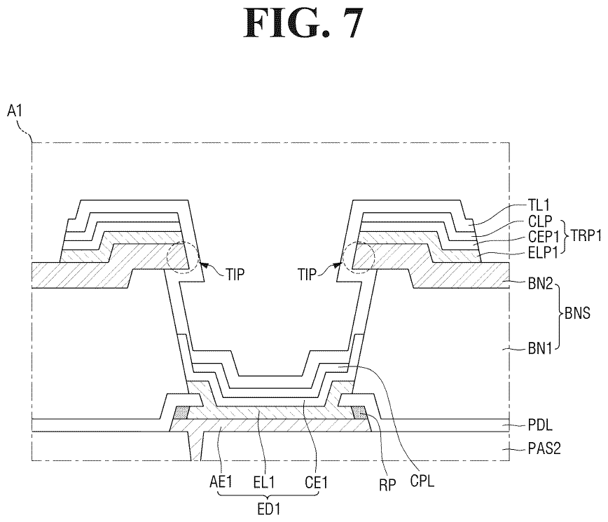

FIG. 7 is an enlarged cross-sectional view showing the area A1 of FIG. 6. For example, FIG. 7 may illustrate the first emission area EA1 of FIG. 6.

The light-emitting elements ED1, ED2, and ED3 may be disposed on the second passivation layer PAS2. The light-emitting elements ED1, ED2, and ED3 may include the pixel electrodes AE1, AE2, and AE3, the emissive layers EL1, EL2, and EL3, and the common electrodes CE1, CE2, and CE3. Holes from the pixel electrodes AE1, AE2, and AE3 and electrons from the common electrodes CE1, CE2, and CE3 may combine with one another in the emissive layers EL1, EL2, and EL3 to emit light.

The pixel electrodes AE1, AE2, and AE3 may be disposed in the emission areas EA1, EA2, and EA3, respectively. The pixel electrodes AE1, AE2, and AE3 may include the first pixel electrode PE1 disposed in the first emission area EA1, the second pixel electrode PE2 disposed in the second emission area EA2, and the third pixel electrode PE3 disposed in the third emission area EA3. Each of the pixel electrodes AE1, AE2, and AE3 may be spaced apart from the others on the second passivation layer PAS2. The pixel electrodes AE1, AE2, and AE3 may be disposed in different emission areas EA1, EA2, and EA3, respectively.

The pixel electrodes AE1, AE2, and AE3 may be electrically connected to the drain electrode DE of the corresponding thin-film transistors TFT through the corresponding first and second connection electrodes CNE1 and CNE2. According to an embodiment of the present disclosure, the pixel electrodes AE1, AE2, and AE3 may have a stacked structure of a material layer having a high work function, such as indium-tin-oxide (ITO), indium-zinc-oxide (IZO), zinc oxide (ZnO), and/or indium oxide (In₂O₃), and a reflective material layer, such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), or a suitable mixture thereof. A layer having a higher work function may be disposed on a higher layer than that of a reflective material layer, so that it may be closer to the emissive layers EL1, EL2, and EL3. For example, the pixel electrodes AE1, AE2, and AE3 may have, but is not limited to, a multilayered structure of ITO/Mg, ITO/MgF, ITO/Ag, and/or ITO/Ag/ITO.

The pixel-defining layer PDL may be positioned on the second passivation layer PAS2 and the pixel electrodes AE1, AE2, and AE3, and may expose at least partially the pixel electrodes AE1, AE2, and AE3. The pixel-defining layer PDL may define the emission areas EA1, EA2, and EA3. The pixel-defining layer PDL may cover edges of the pixel electrodes AE1, AE2, and AE3.

The pixel-defining layer PDL may include an organic or inorganic insulating material. According to an embodiment where the display area DA includes the continuous common electrode CE as shown in FIG. 5, the pixel-defining layer PDL may be an organic film including (e.g., made of) an acrylic resin, an epoxy resin, a phenol resin, a polyamide resin, a polyimide resin, and/or the like. As another example, in the display device including the emissive layers EL1, EL2, and EL3, and the common electrodes CE1, CE2, and CE3 that are spaced apart from one another as shown in FIGS. 6 and 7, the pixel-defining layer PDL may include one or more inorganic insulating materials selected from the group consisting of aluminum oxide, titanium oxide, tantalum oxide, hafnium oxide, zinc oxide, silicon oxide, silicon nitride, and silicon oxynitride.

According to an embodiment, a spacer 191 may be disposed on the pixel-defining layer PDL, as shown in FIG. 5. The spacer 191 may support a mask during a process of fabricating the emissive layer EL. The spacer 191 may be formed of an organic layer, such as an acryl resin, an epoxy resin, a phenolic resin, a polyamide resin, and/or a polyimide resin.

The emissive layer EL is formed on the pixel electrodes AE1 and AE2. The emissive layer EL may include an organic material to emit light of a desired color (e.g., a certain or predetermined color). For example, the emissive layer EL may include a hole transporting layer, an organic material layer, and an electron transporting layer. The organic material layer may include a host and a dopant. The organic material layer may include a material that emits a desired color light (e.g., a predetermined color light), and may be formed using a phosphor or a fluorescent material.

The common electrode CE is formed on the emissive layer EL. The common electrode CE may be formed to cover the emissive layer EL. According to an embodiment, the common electrode CE may be a common layer that is commonly formed in the emission areas EA1 and EA2 as shown in FIG. 5. A capping layer may be formed on the common electrode CE.

According to an embodiment, a bank structure BNS may be disposed on the pixel-defining layer PDL as shown in FIGS. 6 and 7. The bank structure BNS may have a structure in which bank layers BN1 and BN2 including different materials from each other are sequentially stacked on one another. A plurality of openings formed in the bank structure BNS of the emission material layer EML may be defined along the boundary of the bank structure BNS. The openings may include the first to third emission areas EA1, EA2, and EA3. The first bank layer BN1 and the second bank layer BN2 of the bank structure BNS may surround (e.g., around peripheries of) the emission areas EA1, EA2, and EA3, and may be disposed to overlap with a light-blocking layer BM, which will be described in more detail below. The light-emitting elements ED1, ED2, and ED3 of the display device 10 may be in line with the openings of the bank structure BNS.

The first bank layer BN1 may be disposed on the pixel-defining layer PDL. The first bank layer BN1 may include a metal having a high electrical conductivity. For example, the first bank layer BN1 may include aluminum (Al) having a high electrical conductivity.

Referring to FIG. 7, the first bank layer BN1 may be disposed on the pixel-defining layer PDL. A side surface of the first bank layer BN1 may be recessed more than a side surface of the pixel-defining layer PDL away from the emission areas EA1, EA2, and EA3. The side surface of the first bank layer BN1 may be recessed more than that of the second bank layer BN2 away from the emission areas EA1, EA2, and EA3, which will be described in more detail below.

According to an embodiment, the first bank layer BN1 may include a metal material. According to an embodiment, the first bank layer BN1 may include aluminum (Al) or an alloy of aluminum (Al).

The second bank layer BN2 may be disposed on the first bank layer BN1. The second bank layer BN2 may include tips TIP that protrude from the first bank layer BN1. A side surface of the second bank layer BN2 may protrude toward the emission areas EA1, EA2, and EA3 more than a side surface of the first bank layer BN1. As the side surface of the second bank layer BN2 protrudes toward the emission areas EA1, EA2, and EA3 more than the side surface of the first bank layer BN1, an undercut structure of the first bank layer BN1 may be formed below the tips TIP of the second bank layer BN2.

In the display device 10 according to an embodiment, the bank structure BNS includes the protruding tips TIP toward the emission areas EA1, EA2, and EA3, and thus, the emissive layers EL1, EL2, and EL3 and common electrodes CE1, CE2, and CE3 may be formed via deposition and etching processes rather than a mask process. In addition, it may be possible to form different layers individually in different emission areas EA1, EA2, and EA3 via a deposition process. For example, even though the emissive layers EL1, EL2, and EL3 and the common electrodes CE1, CE2, and CE3 of the light-emitting elements ED1, ED2, and ED3 are formed via a deposition process without using a mask, the deposited materials may not be connected to each other between the emission areas EA1, EA2, and EA3, and may be disconnected from each other by the tips TIP of the second bank layer BN2 with the bank structure BNS therebetween. By forming a material for forming a certain layer on the front surface of the display device 10, and then etching and removing a layer formed at an unwanted location, it may be possible to form different layers individually in different emission areas EA1, EA2, and EA3. In the display device 10, different light-emitting elements ED1, ED2, and ED3 may be formed for different emission areas EA1, EA2, and EA3 via deposition and etching processes without using a mask process, and unnecessary configurations may be eliminated from the display device 10, and thus, the non-display area NDA may be reduced.

The shape of the side surfaces of the bank structure BNS may be formed due to a difference in an etch rate during an etching process, since the first and second bank layers BN1 and BN2 include different materials from each other. According to an embodiment, the second bank layer BN2 may include a material having an etch rate slower than that of the first bank layer BN1, and accordingly, the first bank layer BN1 may be further etched during the etching process, such that the lower surface of the tips TIP of the second bank BN2 may be exposed, thereby forming an undercut.

The second bank layer BN2 may include a metal material different from the metal material of the first bank layer BN1. It may be desired that the metal material of the second bank layer BN2 is removed by dry etching along with the metal material of the first bank layer BN1 and is not etched by wet etching, or more slowly etched than the first bank layer BN1. According to an embodiment, the first bank layer BN1 may include aluminum (Al), and the second bank layer BN2 may include titanium (Ti).

The tips TIP of the second bank layer BN2 may overlap with the common electrodes CE1, CE2, and CE3 in the thickness direction (e.g., the z-axis direction) of the substrate SUB. In addition, the tips TIP of the second bank layer BN2 may overlap with the pixel-defining film PDL in the thickness direction of the substrate SUB. The common electrodes CE1, CE2, and CE3 may be formed below the lower surface of the tips TIP of the second bank layer BN2. The maximum vertical distance from the substrate SUB to the common electrodes CE1, CE2, and CE3 may be smaller than the maximum vertical distance from the substrate SUB to the second bank layer BN2.

According to an embodiment, the emissive layer EL may include the first emissive layer EL1, the second emissive layer EL2, and the third emissive layer EL3 disposed in different emission areas EA1, EA2, and EA3, as shown in FIGS. 6 and 7. The first emissive layer EL1 may be disposed on the first pixel electrode AE1 in the first emission area EA1, the second emissive layer EL2 may be disposed on the second pixel electrode AE2 in the second emission area EA2, and the third emissive layer EL3 may be disposed on the third pixel electrode AE3 in the third emission area EA3. For example, the first emissive layer EL1 may emit red light of the first color, the second emissive layer EL2 may emit green light of the second color, and the third emissive layer EL3 may emit blue light of the third color.

The emissive layers EL1, EL2, and EL3 may be in direct contact with side surfaces of the first bank layer BN1. The contact area between the common electrodes CE1, CE2, and CE3 and the side surface of the first bank layer BN1 may be greater than the contact area between the emissive layers EL1, EL2 EL3 and the side surface of the first bank layer BN1. The common electrodes CE1, CE2, and CE3 on the side surface of the first bank layer BN1 may have a larger area, or may be disposed at a higher position on the side surface of the first bank layer BN1 than the emissive layers EL1, EL2, and EL3. Because the common electrodes CE1, CE2, and CE3 of different light-emitting elements ED1, ED2, and ED3 are electrically connected to each other through the first bank layer BN1, they may be in contact with the first bank layer BN1 in a larger area.

Because the light-emitting elements ED1, ED2, and ED3 are formed in the openings of the bank structure BNS, the thickness of the first bank layer BN1 may be greater than (e.g., much greater than) the thickness of the second bank layer BN2.

According to an embodiment, the pixel-defining layer PDL may be disposed on the pixel electrodes AE1, AE2, and AE3, and may be spaced apart from upper surfaces of the pixel electrodes AE1, AE2, and AE3. A temporary protective layer may be disposed between the inorganic pixel-defining layer PDL and the pixel electrodes AE1, AE2, and AE3, and then removed during the process of fabricating the display device 10. Accordingly, the lower surface of the pixel-defining layer PDL may be spaced apart from the pixel electrodes AE1, AE2, and AE3 where the temporary protective layer is partially removed. The emissive layers EL1, EL2, and EL3 may be disposed where the pixel-defining layer PDL is spaced apart from the pixel electrodes AE1, AE2, and AE3. The deposition process of the emissive layers EL1, EL2, and EL3 may be performed such that the material for the emissive layers EL1, EL2, and EL3 is deposited in an inclined direction, rather than a direction perpendicular to or substantially perpendicular to the upper surface of the substrate 110. Accordingly, the emissive layers EL1, EL2, and EL3 may be disposed to fill the space between the pixel electrodes AE1, AE2, and AE3 and the pixel-defining layer PDL. A portion of the temporary protective layer that is not removed may remain as a residual pattern RP where the pixel electrodes AE1, AE2, and AE3 and the pixel-defining layer PDL are spaced apart from each other. Although the side surface of the residual pattern RP facing the emission areas EA1, EA2, and EA3 is more depressed than the side surface of the pixel-defining layer PDL in the example illustrated in FIGS. 6 and 7, the present disclosure is not limited thereto. The side surface of the residual pattern RP may protrude from the side surface of the pixel-defining layer PDL toward the emission areas EA1, EA2, and EA3, or may be aligned or substantially aligned with the side surface of the pixel-defining layer PDL.

The common electrodes CE1, CE2, and CE3 may be disposed on the emissive layers EL1, EL2, and EL3. The common electrodes CE1, CE2, and CE3 include a transparent conductive material to allow light generated in the emissive layers EL1, EL2, and EL3 to exit. The common electrodes CE1, CE2, and CE3 may receive a common voltage or a low-level voltage. When the pixel electrodes AE1, AE2, and AE3 receive a voltage equal to the data voltage and the common electrodes CE1, CE2, and CE3 receive the low-level voltage, a potential difference may be formed between the pixel electrodes AE1, AE2, and AE3 and the common electrodes CE1, CE2, and CE3, so that the emissive layers EL1, EL2, and EL3 may emit light.

For example, the common electrodes CE1, CE2, and CE3 may include, but is not limited to, silver (Ag). The common electrodes CE1, CE2, and CE3 may include a material layer having a small work function, such as Li, Ca, LiF/Ca, LiF/Al, Al, Mg, Pt, Pd, Ni, Au, Nd, Ir, Cr, BaF, and/or Ba, or a suitable compound or a suitable mixture thereof (e.g., a mixture of Ag and Mg). The common electrodes CE1, CE2, and CE3 may further include a transparent metal oxide layer disposed on the material layer having the small work function.

The common electrodes CE1, CE2, and CE3 may include the first common electrode CE1, the second common electrode CE2, and the third common electrode CE3, which are disposed in different emission areas EA1, EA2, and EA3 from each other. The first common electrode CE1 may be disposed on the first emissive layer EL1 in the first emission area EA1, the second common electrode CE2 may be disposed on the second emissive layer EL2 in the second emission area EA2, and the third common electrode CE3 may be disposed on the third emissive layer EL3 in the third emission area EA3.

In the display device 10 according to an embodiment of the present disclosure, the common electrodes CE1, CE2, and CE3 disposed in the different emission areas EA1, EA2, and EA3 from each other are not directly connected to each other, but may be electrically connected to each other through the first bank layer BN1 of the bank structure BNS. Accordingly, parts of the common electrodes CE1, CE2, and CE3 may be in contact with the side surfaces of the first bank layer BN1 of the bank structure BNS.

A capping layer CPL may be disposed on the common electrodes CE1, CE2, and CE3. The capping layer CPL may include an inorganic insulating material to cover the light-emitting elements ED1, ED2, and ED3. The capping layer CPL may prevent or substantially prevent the light-emitting elements ED1, ED2, and ED3 from being damaged by outside air. In an embodiment, the capping layer CPL may include aluminum oxide, titanium oxide, tantalum oxide, hafnium oxide, zinc oxide, silicon oxide, silicon nitride, and/or silicon oxynitride.

Referring to FIGS. 6 and 7, a plurality of trace patterns TRP1, TRP2, and TRP3 may be disposed on the second bank layer BN2. The trace patterns TRP1, TRP2, and TRP3 may include organic patterns ELP1, ELP2, and ELP3, electrode patterns CEP1, CEP2, and CEP3, and capping patterns CLP. The plurality of trace patterns TRP1, TRP2, and TRP3 may be arranged to surround around the peripheries of the emission areas EA1, EA2, and EA3. The trace patterns TRP1, TRP2, and TRP3 may be partially etched during the process of fabricating the display device 10, so that a pattern shape may change.

The trace patterns TRP1, TRP2, and TRP3 may be formed by being disconnected from the emissive layers EL1, EL2, and EL3, the common electrodes CE1, CE2, and CE3, and the capping layer CPL in the emission areas EA1, EA2, and EA3 as the bank structure BNS includes the tips TIP.

The plurality of organic patterns ELP1, ELP2, and ELP3 may be disposed on the second bank layer BN2 to partially overlap with the second bank layer BN2. The organic patterns ELP1, ELP2, and ELP3 may include the same materials as those of the emissive layers EL1, EL2, and EL3, respectively.

The electrode patterns CEP1, CEP2, and CEP3 may be disposed on the organic patterns ELP1, ELP2, and ELP3, respectively. The electrode patterns CEP1, CEP2, and CEP3 may include the first electrode pattern CEP1, the second electrode pattern CEP2, and the third electrode pattern CEP3 that include the same materials as those of the common electrodes CE1, CE2, and CE3, respectively.

The plurality of capping patterns CLP may be positioned on the plurality of electrode patterns CEP1, CEP2, and CEP3. The capping patterns CLP may include the same material as that of the capping layer CPL. The arrangement relationship between the capping patterns CLP and the electrode patterns CEP1, CEP2, and CEP3 may be the same or substantially the same as the arrangement relationship between the capping layers CPL and the common electrodes CE1, CE2, and CE3.

The thin-film encapsulation layer ENC may cover the emission material layer EML. As shown in FIG. 5, the thin-film encapsulation layer ENC may completely cover the common electrode layer CE. As another example, as shown in FIGS. 6 and 7, the thin-film encapsulation layer ENC may cover the light-emitting elements ED1, ED2, and ED3, the bank structure BNS, and the trace patterns TRP1, TRP2, and TRP3.

The thin-film encapsulation layer ENC may include at least one inorganic layer to prevent or substantially prevent permeation of oxygen and/or moisture into the emission material layer EML. The thin-film encapsulation layer ENC may include at least one organic layer to protect the emission material layer EML from particles, such as dust. According to an embodiment of the present disclosure, the thin-film encapsulation layer ENC may include a first inorganic encapsulation film TFE1, an organic encapsulation film TFE2, and a second inorganic encapsulation film TFE3, which are stacked on one another in that order. The first inorganic encapsulation film TFE1 and the second inorganic encapsulation film TFE3 may be inorganic encapsulation layers, and the organic encapsulation film TFE2 disposed between them may be an organic encapsulation layer.

Each of the first inorganic encapsulation film TFEL1 and the second inorganic encapsulation film TFEL3 may include one or more inorganic insulating materials. The inorganic insulating materials may include aluminum oxide, titanium oxide, tantalum oxide, hafnium oxide, zinc oxide, silicon oxide, silicon nitride, and/or silicon oxynitride.

The organic encapsulation film TFE2 may include a polymer-based material. The polymer-based material may include an acrylic resin, an epoxy resin, polyimide, polyethylene, and/or the like. For example, the organic encapsulation film TFEL2 may include an acrylic resin, such as polymethyl methacrylate and polyacrylic acid. The organic encapsulation film TFE2 may be formed by curing a monomer or by applying a polymer.

According to an embodiment, the first inorganic encapsulation film TFE1 may include first to third inorganic layers TL1, TL2, and TL3 disposed in line with the different emission areas EA1, EA2, and EA3, respectively, as shown in FIG. 6. The first inorganic layer TL1, the second inorganic layer TL2, and the third inorganic layer TL3 may include an inorganic insulating material to cover the light-emitting elements ED1, ED2, and ED3, respectively. The first inorganic layer TL1, the second inorganic layer TL2, and the third inorganic layer TL3 may prevent or substantially prevent the light-emitting elements ED1, ED2, and ED3 from being damaged by outside air. The first inorganic layer TL1, the second inorganic layer TL2, and the third inorganic layer TL3 may cover the organic patterns ELP1, ELP2, and ELP3, the electrode patterns CEP1, CEP2, and CEP3, and the capping pattern CLP, thereby preventing or substantially preventing the patterns disposed on the bank structure BNS from being delaminated during the process of fabricating the display device 10.

Because the first inorganic layer TL1, the second inorganic layer TL2, and the third inorganic layer TL3 may be formed by chemical vapor deposition (CVD), they may be formed along steps of the layer on which they are deposited. For example, the first inorganic layer TL1, the second inorganic layer TL2, and the third inorganic layer TL3 may form thin films even under the undercut by the tips TIP of the bank structure BNS.

The first inorganic layer TL1 may be disposed on the first light-emitting element ED1 and the first electrode pattern CEP1. The first inorganic layer TL1 may be disposed to cover the first light-emitting element ED1, the capping layer CAP, and the side surface of the second bank layer BL2 adjacent to the first common electrode CE1, and may cover the first organic pattern ELP1, the first electrode pattern CEP1, and the capping pattern CLP. However, the first inorganic layer TL1 may not overlap with the second opening or the third opening, and may be disposed only on the first opening and the bank structure BNS around (e.g., adjacent to) the first opening. Although the thickness of the first inorganic layer TL1 that encapsulates along the outer surface of the first trace pattern TRP1 and the light-emitting element ED1 is not uniform in the example shown in FIGS. 4 to 6, the first organic layer TL1 may be disposed along the upper and side surfaces of the first trace pattern TRP1, the side and lower surfaces of the second bank layer BN2, the side surface of the first bank layer BN1 and the upper surface of the first common electrode CE1, with a uniform or substantially uniform thickness.

The second inorganic layer TL2 may be disposed on the second light-emitting element ED2 and the second electrode pattern CEP2. However, the second inorganic layer TL2 may not overlap with the first opening or the third opening, and may be disposed only on the second opening and the bank structure BNS around (e.g., adjacent to) the second opening.

The third inorganic layer TL3 may be disposed on the third light-emitting element ED3 and the third electrode pattern CEP3. However, the third inorganic layer TL3 may not overlap with the first opening or the second opening, and may be disposed only on the third opening and the bank structure BNS around (e.g., adjacent to) the third opening.

The first inorganic layer TL1 may be formed after the first common electrode CE1 is formed. The second inorganic layer TL2 may be formed after the second common electrode CE2 is formed. The third inorganic layer TL3 may be formed after the third common electrode CE3 is formed. Accordingly, the first to third inorganic layers TL1, TL2, and TL3 may be disposed to cover the different electrode patterns CEP1, CEP2, and CEP3 and the organic patterns ELP1, ELP2, and ELP3, respectively. When viewed from the top (e.g., in a plan view), each of the first inorganic layer TL1, the second inorganic layer TL2, and the third inorganic layer TL3 may have the same or similar boundary as that of the corresponding first to third trace patterns TRP1, TRP2, and TRP3, and may have a larger area than that of the corresponding opening of the bank structure BNS or the corresponding emission areas EA1, EA2, and EA3. The first inorganic layer TL1, the second inorganic layer TL2, and the third inorganic layer TL3 may be spaced apart from each other on the bank structure BNS. Accordingly, a portion of the second bank layer BN2 may not overlap with the first to third inorganic layers TL1, TL2, and TL3, and a part of the upper surface of the second bank layer BN2 may be exposed without being covered by the first to third inorganic layers TL1, TL2, and TL3 in the space between the first to third inorganic layers TL1, TL2, and TL3. The exposed upper surface of the second bank layer BNL2 may be in direct contact with the organic encapsulation film TFE2 of the thin-film encapsulation layer TFEL.

The touch sensor layer SENL may be disposed on the thin-film encapsulation layer ENC. The touch sensor layer SENL may include a touch buffer layer TBF, a touch insulating layer TIL, touch electrodes TE, and a touch protective layer TPR.

The touch buffer layer TBF may be disposed on the thin-film encapsulation layer ENC. The touch buffer layer TBF may have insulating properties and optical features. The touch buffer layer TBF may include at least one inorganic film. However, the present disclosure is not limited thereto, and the touch buffer layer TBF may be eliminated as needed or desired. In some embodiments, connection electrodes electrically connecting between the touch electrodes may be disposed on the touch buffer layer TBF. The connection electrodes may include (e.g., may be made up of) a single layer of molybdenum (Mo), titanium (Ti), copper (Cu), aluminum (Al), or indium tin oxide (ITO), or may include (e.g., may be made up of) a stacked structure of aluminum and titanium (Ti/Al/Ti), a stacked structure of aluminum and ITO (ITO/Al/ITO), an APC alloy, and/or a stack structure of an APC alloy and ITO (e.g., ITO/APC/ITO).

The touch insulating layer TIL may cover the touch buffer layer TBF. The touch insulating layer TIL may have insulating properties. For example, the touch insulating layer TIL may be an inorganic layer including at least one selected from the group consisting of a silicon nitride layer, a silicon oxynitride layer, a silicon oxide layer, a titanium oxide layer, and an aluminum oxide layer.

Some of the touch electrodes TE may be disposed on the touch insulating layer TIL. The touch electrodes TE may not overlap with the first to third emission areas EA1, EA2, and EA3. The touch electrodes TE may include (e.g., may be made up of) a single layer of molybdenum (Mo), titanium (Ti), copper (Cu), aluminum (Al), or indium tin oxide (ITO), or may include (e.g., may be made up of) a stacked structure of aluminum and titanium (Ti/Al/Ti), a stacked structure of aluminum and ITO (ITO/Al/ITO), an APC alloy, and/or a stacked structure of an APC alloy and ITO (e.g., ITO/APC/ITO).

The touch protective layer TPR may cover the touch electrodes TE and the touch insulating layer TIL. The touch protective layer TPR may have insulating properties and optical features. The touch protective layer TPR may be formed of any of the above-listed materials of the touch insulating layer TIL.

A light-blocking layer BM may be disposed on the touch sensor layer SENL. The light-blocking layer BM may overlap with the pixel-defining layer PDL and/or the bank structure BNS. The light-blocking layer BM may include a light-absorbing material. For example, the light-blocking layer BM may include an inorganic black pigment or an organic black pigment. The inorganic black pigment may be, but is not limited to, carbon black, and the organic black pigment may include, but is not limited to, at least one of lactam black, perylene black, and/or aniline black. The light-blocking layer BM may prevent or substantially prevent visible light from penetrating and mixing colors between the first to third emission areas EA1, EA2, and EA3 to improve the color gamut of the display device 10.

According to an embodiment, the color filter layer CF may overlap with the emission areas EA1, EA2, and EA3, and may be disposed on the touch protective layer TPR and the light-blocking layer BM.

The color filter layer CF may include a first color filter CF1, a second color filter CF2, and a third color filter CF3 disposed in different emission areas EA1, EA2, and EA3, respectively. The color filters CF1, CF2, and CF3 may include a colorant such as a dye and a pigment that absorbs light in wavelength ranges other than light in a particular wavelength range, and may be disposed in association with the light exiting from the emission areas EA1, EA2, and EA3. For example, the first color filter CF1 may be a red color filter that is disposed to overlap with the first emission area EA1, and transmits only the first red light. The second color filter CF2 may be a green color filter that is disposed to overlap with the second emission area EA2, and transmits only the green second light. The third color filter CF3 may be a blue color filter that is disposed to overlap with the third emission area EA3, and transmits only the blue third light.

Although the color filters CF1, CF2, and CF3 are spaced apart from one another on the light-blocking layer BM in the example illustrated in FIG. 6, the present disclosure is not limited thereto. In other words, the color filters CF1, CF2, and CF3 may partially overlap with one another. In other words, different color filters CF1, CF2, and CF3 may not overlap with the emission areas EA1, EA2, and EA3, but may overlap with one another on the light-blocking layer BM.

The organic planarization layer ORL may be disposed on the sensor electrode layer SENL. The organic planarization layer ORL may provide a flat or substantially flat surface over the elements having different heights, so that the polarizing film PF may be easily attached thereon, and the reflection of external light caused by the polarizing film PF may be prevented or substantially prevented from being recognized by a user.

The organic planarization layer ORL may include an overcoat layer OC. The overcoat layer OC may include (e.g., may be made of) an organic material, and may include an acryl resin, an epoxy resin, a phenolic resin, a polyamide resin, a polyimide resin, and/or the like.

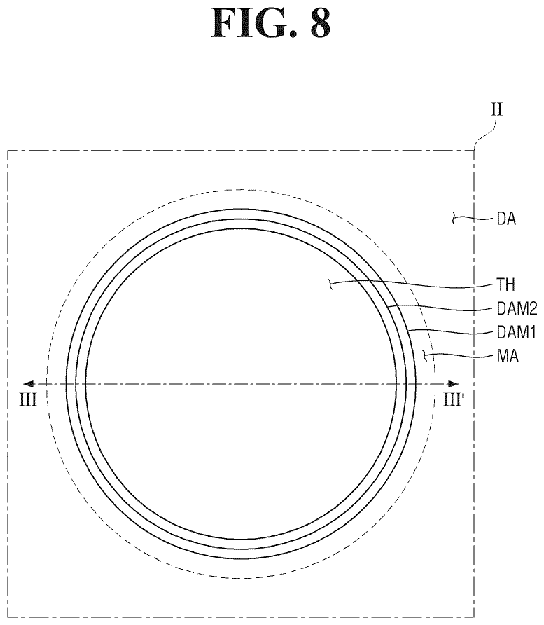

FIG. 8 is an enlarged plan view of the area II of FIG. 2.

Referring to FIG. 8, the middle area MA may surround (e.g., around a periphery of) the through hole TH, and may be located between the through hole TH and the display area DA. A first dam DAM1 and a second dam DAM2 may be located in the middle area MA. The second dam DAM2 surrounds (e.g., around a periphery of) the through hole TH, and the first dam DAM1 surrounds (e.g., around a periphery of) the second dam DAM2.

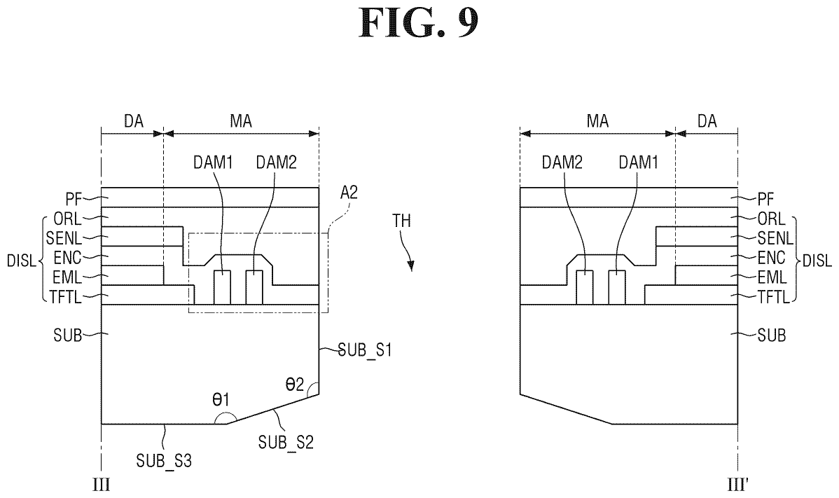

FIG. 9 is a cross-sectional view showing an example of the display panel taken along the line III-III′ of FIG. 8.

Referring to FIG. 9, the through hole TH may penetrate the substrate SUB, the thin-film transistor layer TFTL, the emission material layer EML, the thin-film encapsulation layer ENC, the touch sensor layer SENL, and the polarizing film PF included in the display panel 100. The through hole TH may be formed via a laser processing process. The through hole TH may be covered by the cover window CW (e.g., see FIG. 3), and the optical device OPD may be disposed inside the through hole TH.

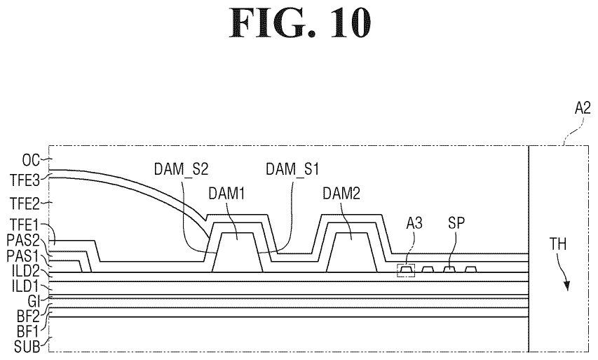

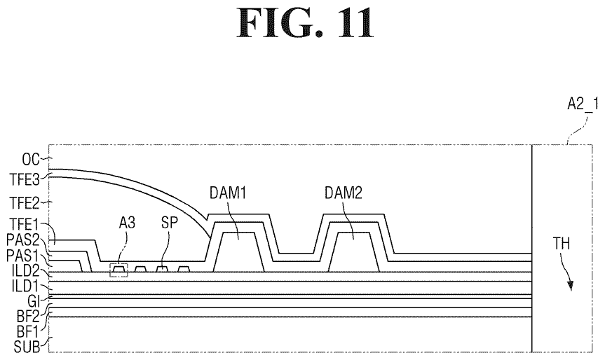

A plurality of light-emitting elements is disposed in the display area DA, but not in the middle area MA. The middle area MA may include the first dam DAM1, the second dam DAM2, and a plurality of edge structures SP (e.g., see FIGS. 10 and 11). The first inorganic encapsulation film TFE1 disposed on the light-emitting element adjacent to the boundary between the display area DA and the middle area MA may cover the middle area MA, and may cover the first dam DAM1, the second dam DAM2, and the plurality of edge structures SP in the middle area MA.

The substrate SUB may include a first surface SUB_S1, a second surface SUB_S2, and a third surface SUB_S3 in the middle area MA. The second surface SUB_S2 of the substrate SUB may connect the third surface SUB_S3 with the first surface SUB_S1 of the substrate SUB. The second surface SUB_S2 of the substrate SUB may be formed by a laser processing for forming the through hole TH, and may be an inclined surface toward the through hole TH. In more detail, the second surface SUB_S2 of the substrate SUB may be formed by spraying an etching solution after irradiating a laser. An angle θ₁ formed by the third surface SUB_S3 and the second surface SUB_S2 of the substrate SUB may be an obtuse angle, and an angle θ₂ formed by the first surface SUB_S1 and the second surface SUB_S2 of the substrate SUB may be an obtuse angle.

FIG. 10 is an enlarged cross-sectional view showing an example of the area A2 of FIG. 9. FIG. 11 is an enlarged cross-sectional view showing another example of the area A2 of FIG. 9.

Referring to FIGS. 10 and 11, the first dam DAM1 may be disposed on the second interlayer dielectric layer ILD2. The display device 10 may have a structure in which a number of layers are sequentially stacked on one substrate SUB. Some layers of the display device 10 may include (e.g., may be made of) an organic material, and may be formed via a process of directly applying the organic material on the substrate SUB. For example, the organic encapsulation film TFE2 of the thin-film encapsulation layer ENC may contain an organic material, and may flow with a fluidity. The organic material applied on the display area DA may overflow into the non-display area NDA. Accordingly, the first dam DAM1 may be located in the middle area MA, and may prevent or substantially prevent organic materials disposed in the display area DA from overflowing into the through hole TH. The first dam DAM1 may prevent or substantially prevent the organic material applied to the display area DA from overflowing into the non-display area NDA. Therefore, the first dam DAM1 may have a minimum or reduced thickness or height.

In some embodiments, the first dam DAM1 may have a multi-layered structure. The first dam DAM1 may include a layer containing the same material as that of the pixel-defining layer PDL of the display area, and a layer containing the same material as that of the spacer 191. There may be a plurality of first dams DAM1, and a plurality of material layers may be alternately stacked on one another several times. In other words, the first dam DAM1 may have a multi-layered structure in which a first dam layer and a second dam layer are alternately stacked on one another.

The first inorganic encapsulation film TFE1, the organic encapsulation film TFE2, and the second inorganic encapsulation film TFE3 may be disposed on the first dam DAM1. The first dam DAM1 may include a first side surface DAM_S1 facing the through hole, and a second side surface DAM_S2 opposite to the first side surface DAM_S1. The first inorganic encapsulation film TFE1 and the second inorganic encapsulation film TFE3 may be in contact with each other on the first side surface DAM_S1 of the first dam DAM1, without the organic encapsulation film TFE2 therebetween. The organic encapsulation film TFE2 may be disposed on the second side surface DAM_S2, but not on the first side surface DAM_S1.

According to the embodiment, the second dam DAM2 may be located between the through hole TH and the first dam DAM1. The second dam DAM2 may block particles and/or the like from permeating through the through hole TH.

The edge structures SP may be disposed on the second interlayer dielectric layer ILD2 in the middle area MA. The edge structures SP may increase the contact area of the encapsulation film, thereby preventing or substantially preventing delamination and/or cracking of the films around (e.g., adjacent to) the through hole TH. In addition, in the display device where the emissive layer EL and the common electrode CE are formed across the entire surface as shown in FIG. 5, because the emissive layer EL and the common electrode CE are formed of a material having a low step coverage, they may be disconnected by tip structures of the edge structures SP, described in more detail below.

There may be a plurality of edge structures SP. The edge structures SP may be disposed between the first dam DAM1 and the through hole TH, as shown in FIG. 10. However, the present disclosure is not limited thereto, and the edge structures SP may be disposed to be closer to the display area DA than the first dam DAM1 as shown in FIG. 11, such that they overlap with the organic encapsulation film TFE2 in the thickness direction (e.g., the z-axis direction) of the substrate. In some embodiments, some of the edge structures SP may be disposed between the second dam DAM2 and the through hole TH (e.g., as shown in FIG. 10), while some others of the edge structures SP may be disposed where they overlap with the organic encapsulation film TFE2 in the thickness direction of the substrate (e.g., as shown in FIG. 11).

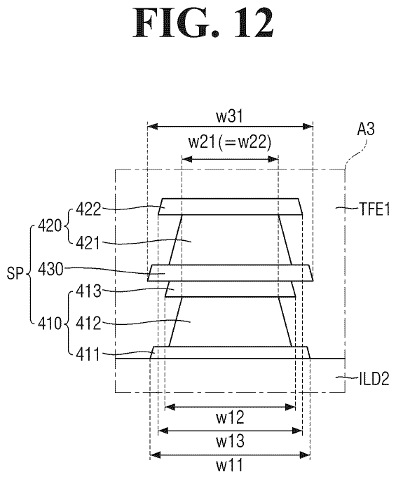

FIGS. 12 through 14 are enlarged cross-sectional views showing examples of the areas A3 of FIGS. 10 and 11. For example, FIGS. 12 through 14 are enlarged cross-sectional views showing an edge structure SP from among the edge structures SP, according to different embodiments.

Referring to FIGS. 12 to 14, each of the edge structures SP (or SP_1, SP_2) may include a lower metal stack 410 (or 410_1, 410_2) and an upper metal stack 420 (or 420_1, 420_2). In the lower metal stack 410, a first sub-metal layer 411 (or 411_1, 411_2), a second sub-metal layer 412 (or 412_1, 412_2), and a third sub-metal layer 413 (or 413_1, 413_2) may be stacked on one another in that order. In the upper metal stack 420 that is disposed on the lower metal stack 410, a fourth sub-metal layer 421 (or 421_1, 421_2) and a fifth sub-metal layer 422 (or 422_1, 422_2) may be stacked on each other sequentially.

Each of the lower metal stack 410 and the upper metal stack 420 may have a tip structure. The lower metal stack 410 may have a tip structure in which a width w12 of the third sub-metal layer 413 is greater than a width w21 of the second sub-metal layer 412. The upper metal stack 420 may have a tip structure in which a width w13 of the fifth sub-metal layer 422 is greater than a width w22 of the fourth sub-metal layer 421. In other words, in the edge structure SP, two tip structures are stacked on each other. With the stack of two tip structures, it may be possible to effectively prevent permeation of outside air, while reducing the number of edge structures SP, when compared to a single tip structure. As the effect of preventing permeation of moisture may be improved, the content of nitride contained in the first inorganic encapsulation film TFE1 may be reduced, thereby increasing light luminance.

The widths of the first to fifth sub-metal layers refer to widths at interfaces forming the tip structures. In more detail, the second sub-metal layer 412 and the third sub-metal layer 413 form a tip structure, and the width at the interface between the second sub-metal layer 412 and the third sub-metal layer 413 is defined as the widths w21 and w12 of the second sub-metal layer 412 and the third sub-metal layer 413. The fourth sub-metal layer 421 and the fifth sub-metal layer 422 form a tip structure, and the width at the interface between the fourth sub-metal layer 421 and the fifth sub-metal layer 422 is defined as the widths w22 and w13 of the fourth sub-metal layer 421 and the fifth sub-metal layer 422. An inorganic layer 430 (or 430_1) described in more detail below forms a tip structure on the third sub-metal layer 413, and the width w31 of the inorganic layer 430 is defined as the width at the boundary between the inorganic layer 430 and the third sub-metal layer 413. The width w11 of the first sub-metal layer 411 refers to the width at the interface with the second interlayer dielectric layer ILD2. The widths of the first sub-metal layer 411, the third sub-metal layer 413, the fifth sub-metal layer 422, and the inorganic layer 430 may be measured with respect to their lower surfaces. The widths of the second sub-metal layer 412 and the fourth sub-metal layer 421 may be measured with respect to their upper surfaces.

The lower metal stack 410 is formed concurrently or substantially simultaneously when the source electrode SE and the drain electrode DE of the thin-film transistor TFT, or in more detail, the connection electrode CNE1, are formed in the display area DA. Accordingly, the first connection electrode CNE1 may include a layer including the same material as that of the first sub-metal layer 411, a layer including the same material as that of the second sub-metal layer 412, and a layer including the same material as that of the third sub-metal layer 413.

The upper metal stack 420 may be formed after forming the pixel electrodes AE1, AE2, and AE3, and before forming the emissive layers EL1, EL2, and EL3. As shown in FIG. 6, if the bank structure BNS is formed in the display area DA, the upper metal stack 420 may be formed together when the bank structure BNS is formed. In this case, the first bank layer BN1 may include the same material as that of the fourth sub-metal layer 421, and the second bank layer BN2 may include the same material as that of the fifth sub-metal layer 422. As shown in FIG. 5, when the emissive layer EL and the common electrode CE are formed across the entire surface, an additional process of forming the upper metal stack 420 may be carried out only in the middle area MA after forming the pixel-defining layer PDL.

The width w11 of the first sub-metal layer 411 may be greater than the width w12 of the third sub-metal layer 413. In the process of etching the pixel electrode after forming the source and drain electrodes, the width w12 of the third sub-metal layer 413 exposed at a higher level may be smaller than the width w11 of the first sub-metal layer 411.

According to the embodiment shown in FIG. 12, the edge structure SP may include the inorganic layer 430 disposed between the lower metal stack 410 and the upper metal stack 420. The width w31 of the inorganic layer 430 may be greater than or equal to the width w12 of the third sub-metal layer 413. If the width w31 of the inorganic layer 430 is greater than the width w12 of the third sub-metal layer 413, the emissive layer EL and the common electrode CE may be effectively cut. The inorganic layer 430 may include one or more inorganic insulating materials selected from the group consisting of aluminum oxide, titanium oxide, tantalum oxide, hafnium oxide, zinc oxide, silicon oxide, silicon nitride, and silicon oxynitride. According to the present embodiment, the inorganic layer 430 may include the same material as that of the pixel-defining layer PDL in the display area DA.

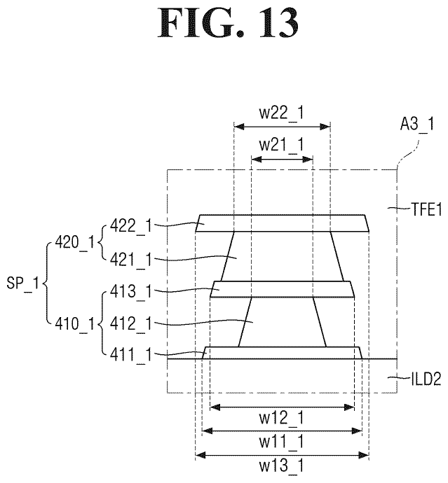

According to the embodiment shown in FIG. 13, the width w22_1 of the fourth sub-metal layer 421_1 may be greater than the width w21_1 of the second sub-metal layer 412_1. During wet etching to form the tip structure of the upper metal stack 420_1, the side surfaces of the second sub-metal layer 412_1 of the lower metal stack 410_1 are also etched, and thus, the width w21_1 of the second sub-metal layer 412_1 may be reduced.

The length of the tip (e.g., w13_1-w22_1) of the upper metal stack 420_1 may be smaller than the length of the tip (e.g., w12_1-w21_1) of the lower metal stack 410_1. The tip of the lower metal stack 410_1 may be strengthened by wet etching twice, so that the length of the tip may be increased.

The thickness of the fourth sub-metal layer 421_1 may be greater than the thickness of the second sub-metal layer 412_1. The thickness of the fourth sub-metal layer 421_1 may be greater than the thickness of the fifth sub-metal layer 422_1.

The width w13_1 of the fifth sub-metal layer 422_1 may be equal to or smaller than the width w11_1 of the first sub-metal layer 411_1. During the process of etching the side surfaces of the first bank layer BN1, the width w13_1 of the fifth sub-metal layer 422_1 exposed at the higher level may be reduced.

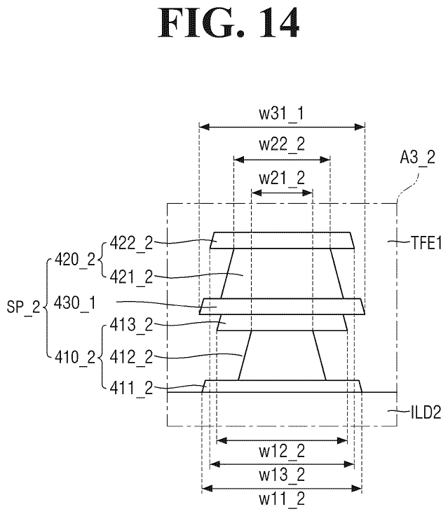

In the embodiment shown in FIG. 14, the edge structure SP_2 includes the inorganic layer 430_1, and the width w22_2 of the fourth sub-metal layer 421_2 is greater than the width w21_2 of the second sub-metal layer 412_2.

The first sub-metal layer 411_2, the third sub-metal layer 413_2, and the fifth sub-metal layer 422_2 may include (e.g., may be made of) the same material as each other, the second sub-metal layer 412_2 and the fourth sub-metal layer 421_2 may include (e.g., may be made of) the same material as each other, and the first sub-metal layer 411_2 and the second sub-metal layer 412_2 may include (e.g., may be made of) different materials from each other. The first sub-metal layer 411_2, the third sub-metal layer 413_2, and the fifth sub-metal layer 422_2 may contain titanium (Ti), and the second sub-metal layer 412_2 and the fourth sub-metal layer 421_2 may contain aluminum (Al).

The first inorganic encapsulation film TFE1 may be in contact with the lower surface of the tip of the edge structure SP_2. The first inorganic encapsulation film TFE1 may be in contact with the lower surface of the third sub-metal layer 413_2 and the lower and upper surfaces of the fifth sub-metal layer 422_2.

Although the emissive layers CE1, CE2, and CE3 and the common electrodes CE1, CE2, and CE3 are spaced apart from one another and are not formed in the middle area MA, such that the edge structure SP is in contact with the first inorganic encapsulation film TFE1 in the examples shown in FIGS. 12 through 14 like that of the example shown in FIG. 6, the present disclosure is not limited thereto.

When the emissive layer EL and the common electrode CE are formed across the entire surface as in the example shown in FIG. 5, residues of the emissive layer EL and the common electrode CE may be formed on a part of the side surfaces and the upper surface of the edge structure SP. In this case, a part of the side surfaces of the edge structure SP may be in contact with the emissive layer EL, and another part of the side surfaces of the edge structure SP may be in contact with the first inorganic encapsulation film TFE1.

Hereinafter, various processes of a method of fabricating an edge structure SP of a display device 10 according to an embodiment of the present disclosure will be described in more detail.

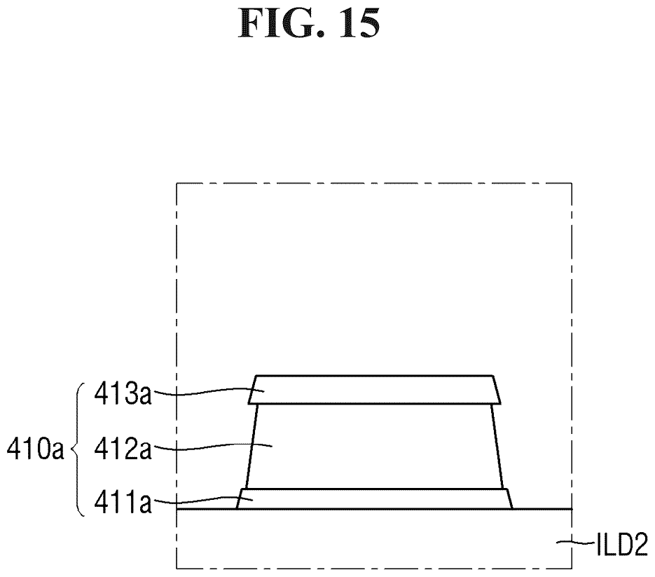

FIGS. 15 through 19 are cross-sectional views showing sequential processes of a method of fabricating a display device according to an embodiment of the present disclosure. For example, FIGS. 15 through 19 may schematically show various processes of fabricating the edge structure SP_2 illustrated in FIG. 14. Hereinafter, for convenience, the formation process of each layer may be not be described in detail, and the formation order of each layer may be described in more detail.

Referring to FIG. 15, a lower metal stack material layer 410a is formed on a second interlayer dielectric layer ILD2. The lower metal stack material layer 410a may include a first sub-metal material layer 411a, a second sub-metal material layer 412a, and a third sub-metal material layer 413a stacked on one another in that order. The lower metal stack material layer 410a may be formed on the second interlayer dielectric layer ILD2 in the middle area MA, while a source electrode SE and a drain electrode DE are formed on the second interlayer dielectric layer ILD2 in the display area DA. While a first passivation layer PAS1, a second passivation layer PAS2, and a pixel electrode layer are formed during subsequent processes, the first passivation layer PAS1, the second passivation layer PAS2, and the pixel electrode layer may not be formed on the lower metal stack material layer 410a.

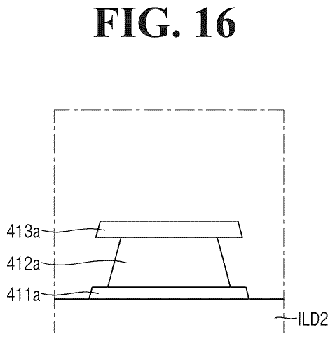

Subsequently, referring to FIG. 16, side surfaces of the second sub-metal material layer 412a are etched. During a wet etching process of patterning the pixel electrode layer in the display area DA to form the pixel electrodes AE1, AE2, and AE3 that are spaced apart from each other, the side surfaces of the second sub-metal material layer 412a in the middle area MA may be etched. As such, a tip structure of the lower metal stack material layer 410a may be obtained.

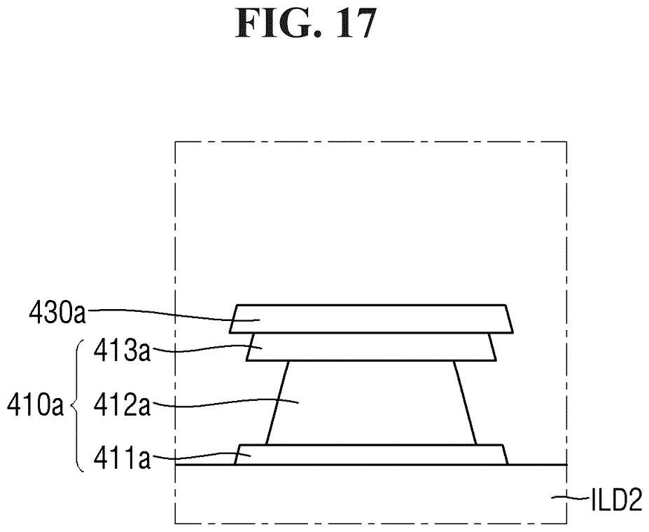

Subsequently, referring to FIG. 17, an inorganic layer 430a is formed on the lower metal stack material layer 410a. In the process of forming the pixel-defining layer PDL in the display area DA, the inorganic layer 430a may be formed on the third sub-metal material layer 413a in the middle area MA. To fabricate the edge structure SP with no inorganic layer 430 as shown in FIG. 13, this process may be omitted.

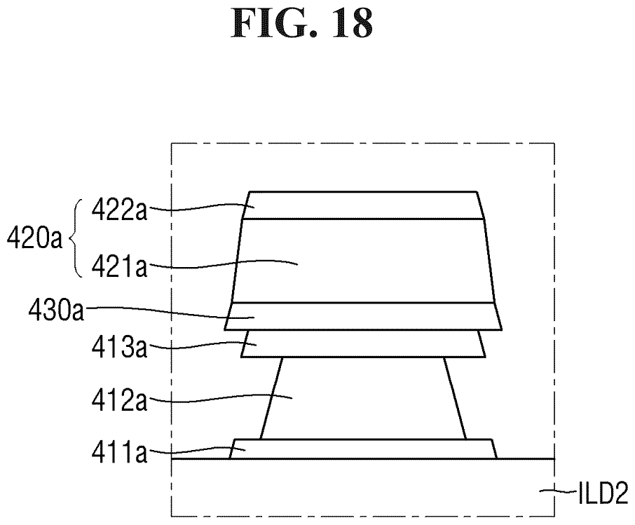

Subsequently, referring to FIG. 18, an upper metal stack material layer 420a is formed on the inorganic layer 430a. The upper metal stack material layer 420a may include a fourth sub-metal material layer 421a and a fifth sub-metal material layer 422a that are sequentially stacked on each other. When the emissive layer EL and the common electrode CE are formed across the entire surface as shown in FIG. 5, the upper metal stack material layer 420a may be formed in the middle area MA between the formation of the pixel-defining layer PDL and the formation of the emissive layer EL. When the bank structure BNS is included as shown in FIG. 6, the upper metal stack material layer 420a may be formed in the middle area MA during the process of forming the bank structure BNS in the display area DA. The first bank layer BN1 and the fourth sub-metal material layer 421a may be formed together, and the second bank layer BN2 and the fifth sub-metal material layer 422a may be formed together. To fabricate the edge structure SP with no inorganic layer 430 as shown in FIG. 13, this process may be omitted.

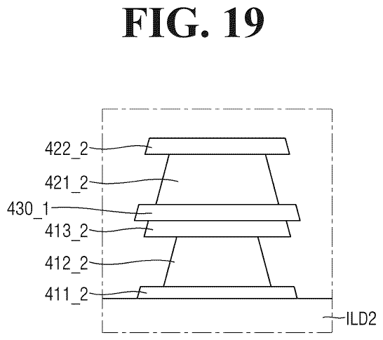

Subsequently, referring to FIG. 19, the side surfaces of the fourth sub-metal material layer 421a and the side surfaces of the second sub-metal material layer 412a are etched. As such, the upper metal stack material layer 420a may have a tip structure, and the tip structure of the lower metal stack material layer 410a may be secondarily reinforced. When the bank structure BNS is included as shown in FIG. 6, during a process of forming an undercut structure of the first bank layer BN1 in the display area DA, the side surfaces of the fourth sub-metal material layer 421a and the side surfaces of the second sub-metal material layer 412a may be etched together in the middle area MA.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate comprising a display area surrounding a through hole, and a middle area between the through hole and the display area;
a light-emitting element on the display area of the substrate, and comprising:
a pixel electrode;
an emissive layer on the pixel electrode; and
a common electrode on the emissive layer;
an edge structure on the middle area of the substrate, and comprising a lower metal stack and an upper metal stack; and
a first inorganic encapsulation film on the light-emitting element and the edge structure,
wherein:
the lower metal stack comprises a first sub-metal layer, a second sub-metal layer on the first sub-metal layer, and a third sub-metal layer on the second sub-metal layer;
the upper metal stack is on the lower metal stack, and comprises a fourth sub-metal layer on the third sub-metal layer, and a fifth sub-metal layer on the fourth sub-metal layer;
a width of the first sub-metal layer is greater than a width of the third sub-metal layer;
the width of the third sub-metal layer is greater than a width of the second sub-metal layer; and
a width of the fifth sub-metal layer is greater than a width of the fourth sub-metal layer.

2. The display device of claim 1, wherein the edge structure comprises an inorganic layer between the lower metal stack and the upper metal stack, and
wherein a width of the inorganic layer is greater than or equal to the width of the third sub-metal layer.

3. The display device of claim 1, wherein the width of the fourth sub-metal layer is greater than the width of the second sub-metal layer.

4. The display device of claim 1, wherein a thickness of the fourth sub-metal layer is greater than a thickness of the fifth sub-metal layer.

5. The display device of claim 1, further comprising:
a pixel-defining layer on the display area of the substrate, and exposing at least a part of the pixel electrode;
a first bank layer on the pixel-defining layer; and
a second bank layer on the first bank layer, and comprising a side surface protruding from a side surface of the first bank layer,
wherein the first bank layer comprises a same material as that of the fourth sub-metal layer, and
wherein the second bank layer comprises a same material as that of the fifth sub-metal layer.

6. The display device of claim 2, further comprising a pixel-defining layer on the display area of the substrate, and exposing at least a part of the pixel electrode,
wherein the inorganic layer comprises a same material as that of the pixel-defining layer.

7. The display device of claim 1, further comprising a thin-film transistor between the substrate and the light-emitting element in the display area, and comprising a semiconductor layer, a source electrode, a drain electrode, and a gate electrode,
wherein the source electrode and the drain electrode comprise:
a layer comprising a same material as that of the first sub-metal layer;
a layer comprising a same material as that of the second sub-metal layer; and
a layer comprising a same material as that of the third sub-metal layer.

8. The display device of claim 1, further comprising:
an organic encapsulation film on the first inorganic encapsulation film;
a second inorganic encapsulation film on the organic encapsulation film; and
a first dam between the substrate and the first inorganic encapsulation film in the middle area,
wherein the first dam comprises a first side surface facing the through hole, and a second side surface opposite to the first side surface, and
wherein the first inorganic encapsulation film and the second inorganic encapsulation film are in contact with each other on the first side surface of the first dam.

9. The display device of claim 8, wherein the organic encapsulation film is on the second side surface of the first dam.

10. The display device of claim 8, wherein the edge structure is between the first dam and the through hole.

11. The display device of claim 8, wherein the edge structure overlaps with the organic encapsulation film in a thickness direction of the substrate.

12. The display device of claim 1, wherein the first sub-metal layer, the third sub-metal layer, and the fifth sub-metal layer comprise titanium (Ti), and
wherein the second sub-metal layer and the fourth sub-metal layer comprise aluminum (Al).

13. The display device of claim 5, wherein the common electrode is in contact with the side surface of the first bank layer.

14. The display device of claim 5, wherein a maximum vertical distance from the substrate to the common electrode is smaller than a maximum vertical distance from the substrate to the second bank layer.

15. The display device of claim 5, further comprising:
an organic pattern on the second bank layer, and comprising a same material as that of the emissive layer; and
an electrode pattern on the organic pattern, and comprising a same material as that of the common electrode,
wherein the emissive layer and the organic pattern are spaced from each other, and
wherein the common electrode and the electrode pattern are spaced from each other.

16. The display device of claim 1, wherein the substrate comprises an inclined surface toward the through hole.

17. The display device of claim 16, further comprising an optical device located in the through hole.

18. A display device comprising:
a substrate comprising a display area surrounding a through hole, and a middle area between the through hole and the display area;
a light-emitting element on the display area of the substrate, and comprising:
a pixel electrode;
an emissive layer on the pixel electrode; and
a common electrode on the emissive layer;
an edge structure on the middle area of the substrate, and comprising a lower metal stack and an upper metal stack; and
a first inorganic encapsulation film on the light-emitting element and the edge structure,
wherein:
the lower metal stack comprises a first sub-metal layer, a second sub-metal layer on the first sub-metal layer, and a third sub-metal layer on the second sub-metal layer;
the upper metal stack is on the lower metal stack, and comprises a fourth sub-metal layer on the third sub-metal layer, and a fifth sub-metal layer on the fourth sub-metal layer;
a thickness of the fourth sub-metal layer is greater than a thickness of the fifth sub-metal layer; and
the first inorganic encapsulation film is in contact with a lower surface of the third sub-metal layer, and a lower surface and an upper surface of the fifth sub-metal layer.

19. The display device of claim 18, wherein the edge structure comprises an inorganic layer between the lower metal stack and the upper metal stack, and
wherein a width of the inorganic layer is greater than or equal to a width of the third sub-metal layer.

20. The display device of claim 18, wherein a width of the first sub-metal layer is greater than a width of the third sub-metal layer, and
wherein a width of the fourth sub-metal layer is greater than a width of the second sub-metal layer.
